(19) United States
(12) Patent Application Publication
(10) Pub. No.: US 2025/0038124 A1
(43) Pub. Date: Jan. 30, 2025

(54) Methods and Structure for Shielding Semiconductors From Ultraviolet Light

(71) Applicant: Taiwan Semiconductor Manufacturing Company, Ltd., Hsinchu (TW)

(72) Inventors: Kuo-Chang Chiang, Hsinchu (TW); Katherine Chiang, Taipei (TW); Chung-Te Lin, Tainan (TW)

(21) Appl. No.: 18/226,849

(22) Filed: Jul. 27, 2023

(51) Int. Cl. H01L 23/552; H01L 29/786

(52) U.S. Cl. CPC H01L 23/552; H01L 29/7869

(57) ABSTRACT

A transistor comprises a colored light shielding layer over the semiconductor layer thereof. The colored light shielding layer reduces exposure of the semiconductor layer to radiation having a wavelength of about 10 nanometers (nm) to about 400 nm. The colored light shielding layer may have a white, black, red, yellow, or gray color. The colored light shielding layer can be formed from a metal oxide film, a p-type oxide semiconductor, or a perovskite. The colored light shielding layer reduces defects that may be generated in the semiconductor layer due to UV light exposure during the manufacturing process, improving device performance and reliability.

### BACKGROUND

An integrated circuit is made of large numbers of transistors. A field-effect transistor is generally composed of a substrate on which an electrically conductive gate electrode controls the flow of current between a source electrode and a drain electrode. An electrically insulating gate dielectric layer separates the gate electrode from the source and drain electrodes. A semiconductor layer bridges the source and drain electrodes, and is in contact with the gate dielectric layer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart illustrating a first method for making a transistor, in accordance with some embodiments.

FIG. 2 is a cross-sectional view of a process step for forming the transistor as described in FIG. 1.

FIG. 3 is a cross-sectional view of a process step for forming the transistor.

FIG. 4 is a cross-sectional view of a process step for forming the transistor.

FIG. 5 is a cross-sectional view of a process step for forming the transistor.

FIG. 6 is a cross-sectional view of a process step for forming the transistor.

FIG. 7 is a cross-sectional view of a process step for forming the transistor.

FIG. 8 is a cross-sectional view of a process step for forming the transistor.

FIG. 9 is a cross-sectional view of a process step for forming the transistor.

FIG. 10 is a cross-sectional view of a process step for forming the transistor.

FIG. 11 is a cross-sectional view showing the final transistor, which is a bottom-gate transistor.

FIG. 12 is a flow chart illustrating a second method for making a transistor, in accordance with some embodiments.

FIG. 13 is a cross-sectional view of a process step for forming the transistor.

FIG. 14 is a cross-sectional view of a process step for forming the transistor.

FIG. 15 is a cross-sectional view of a process step for forming the transistor.

FIG. 16 is a cross-sectional view of a process step for forming the transistor.

FIG. 17 is a cross-sectional view of a process step for forming the transistor.

FIG. 18 is a cross-sectional view of a process step for forming the transistor.

FIG. 19 is a cross-sectional view of a process step for forming the transistor.

FIG. 20 is a cross-sectional view showing the final transistor, which is a top-gate transistor.

FIG. 21 is a flow chart illustrating an second alternative method for making a transistor, in accordance with some embodiments. In this alternative method, the colored light shielding layer also acts as the gate dielectric layer.

FIG. 22 is a cross-sectional view of a process step for forming the transistor.

FIG. 23 is a cross-sectional view of a process step for forming the transistor.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number.

The present disclosure relates to transistors and other structures which are made up of different layers. When the terms “on” or “upon” are used with reference to two different layers (including the substrate), they indicate merely that one layer is on or upon the other layer. These terms do not require the two layers to directly contact each other, and permit other layers to be between the two layers. For example all layers of the transistor can be considered to be “on” the substrate, even though they do not all directly contact the substrate. The term “directly” may be used to indicate two layers directly contact each other without any layers in between them.

The present disclosure relates to methods for producing transistors having increased protection or resistance to ultraviolet light exposure. In this regard, oxide semiconductor (OS) materials have high charge mobility, which permits high speed driving and a low off current for low power consumption. Thus, OS materials are often used as the semiconductor channel material in a metal-oxide-semiconductor field effect transistor (MOSFET) device. However, ultraviolet light exposure during the photolithography process has the potential to cause high power damage, which may contribute to photogenerated holes and creation/ionization of oxygen vacancy states (Vo) in in the body of the OS material and its surface. Exposure to energy of as little as 0.001 to 1 joule may cause heating issues at small pattern sizes. In addition, photoionization generates free electrons and the transition from a neutral to an ionized Vo is accompanied by lattice relaxation, which raises the energy of the ionized Vo. This may promote “defect generation” from atomic exchange with weakly bonded hydrogen, inducing high delta-Vt instability during operation, threshold-voltage shift, and reducing reliability. In addition, as semiconductor channel lengths continue to shrink, the transistor becomes more sensitive to short channel effects. Thus, in the present disclosure, a protective ultraviolet light shielding layer is applied to the semiconductor layer. This reduces the damage done by exposure to photolithographic light.

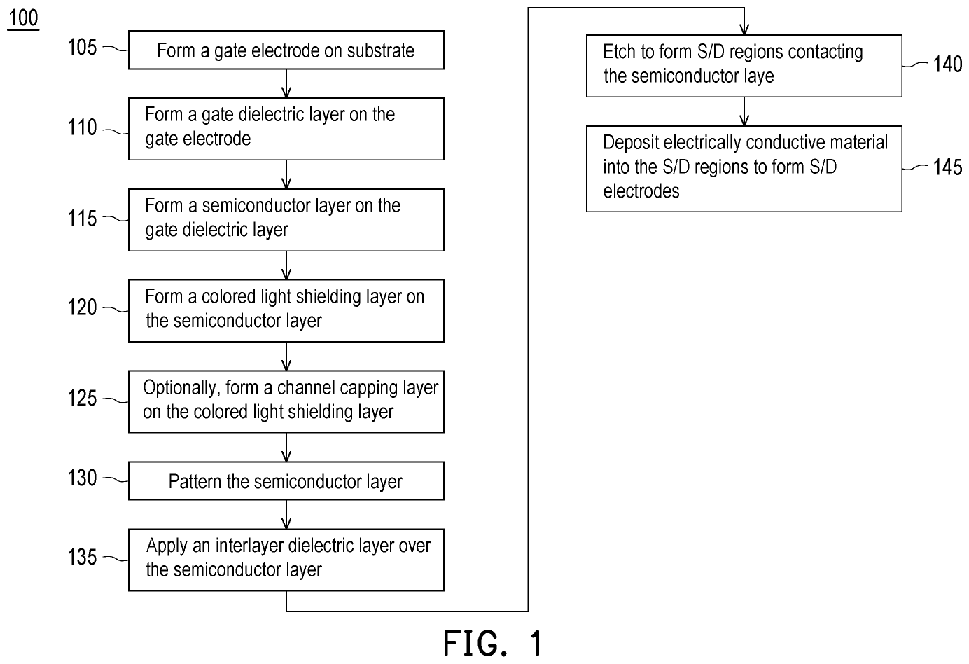

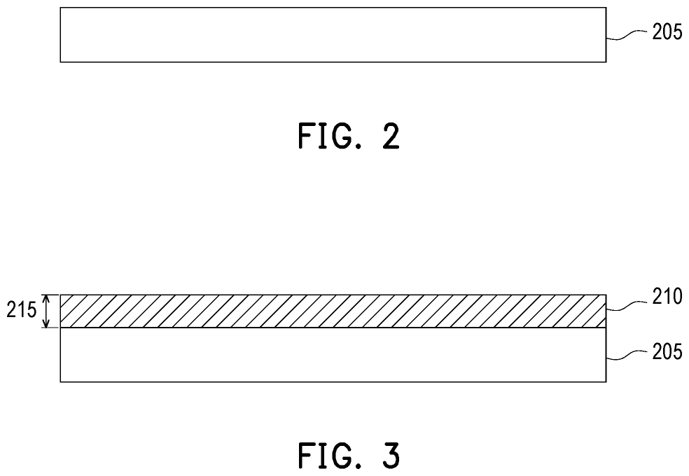

FIG. 1 is a flow chart illustrating a first method 100 for making a transistor, in accordance with some embodiments of the present disclosure. FIGS. 2-11 illustrate various steps of the first method, and these figures are discussed together. These figures are illustrated with reference to a bottom-gate transistor.

Referring first to FIG. 2, a substrate is received or provided. This figure illustrates the beginning state of the substrate prior to making the transistor. The substrate is usually a wafer made of a semiconducting material. Such materials can include silicon, for example in the form of crystalline Si or polycrystalline Si. The substrate can also be made from other elementary semiconductors such as germanium or Al2O3 (sapphire), or may include a compound semiconductor such as silicon carbide (SiC), gallium nitride (GaN), gallium arsenide (GaAs), indium arsenide (InAs), and indium phosphide (InP). In particular embodiments, the wafer substrate is silicon.

Now, in step 105 of FIG. 1 and as illustrated in FIG. 3, a gate electrode 210 is formed. This may be done by forming an electrically insulating (or dielectric) layer, applying and patterning a photoresist layer to place the gate electrode in the desired location, etching the electrically insulating layer, depositing an electrically conductive material to form the gate electrode, and then removing the photoresist layer. It is noted that the electrically insulating layer is not shown in FIG. 3.

The electrically insulating layer is commonly formed using thermal oxidation of a silicon substrate. However, other processes may also be used, such as thermal oxidation, atomic layer deposition (ALD) or chemical vapor deposition (CVD), including plasma-enhanced atomic layer deposition (PEALD) or plasma-enhanced chemical vapor deposition (PECVD). The insulating layer may be formed from silicon dioxide (SiO₂), but can also be made of a high-k dielectric material (which has a dielectric constant greater than 3.9). Examples of suitable high-k dielectric materials include silicon nitride (Si₃N₄), silicon carbide (SiC), hafnium dioxide (HfO₂), zirconium dioxide (ZrO₂), aluminum oxide (Al₂O₃), silicon oxynitride (SiOₓN_{y}), hafnium oxynitride (HfOₓN_{y}) or zirconium oxynitride (ZrOₓN_{y}), or hafnium silicates (ZrSiₓO_{y}) or zirconium silicates (ZrSiₓO_{y}) or silicon carboxynitride (SiCₓO_{y}N_{z}), or hexagonal boron nitride (hBN). Other dielectric materials may include tantalum oxide (Ta₂O₅), nitrides such as silicon nitride, polysilicon, phosphosilicate glass (PSG), fluorosilicate glass (FSG), undoped silicate glass (USG), high-stress undoped silicate glass (HSUSG), and borosilicate glass (BSG).

The photoresist layer may be applied, for example, by spin coating, or by spraying, roller coating, dip coating, or extrusion coating. Typically, in spin coating, the substrate is placed on a rotating platen, which may include a vacuum chuck that holds the substrate in plate. The photoresist composition is then applied to the center of the substrate. The speed of the rotating platen is then increased to spread the resist evenly from the center of the substrate to the perimeter of the substrate. The rotating speed of the platen is then fixed, which can control the thickness of the final photoresist layer.

The photoresist layer may then be baked or cured to remove the solvent and harden the photoresist layer. In some particular embodiments, the baking occurs at a temperature of about 90° C. to about 110° C. The baking can be performed using a hot plate or oven, or similar equipment.

The photoresist layer is then patterned via exposure to radiation. The radiation may be any light wavelength which carries a desired mask pattern, although ultraviolet (“UV”) radiation is typically used at the current time. UV radiation has a wavelength in the range of about 10 nanometers (“nm”) to about 400 nm, such as from KrF lasers (248 nm) or ArF lasers (193 nm). In particular embodiments, extreme ultraviolet (“EUV”) light having a wavelength of about 13.5 nm is used for patterning, as this permits smaller feature sizes to be obtained. This results in some portions of the photoresist layer being exposed to radiation, and some portions of the photoresist not being exposed to radiation. This exposure causes some portions of the photoresist to become soluble in the developer and other portions of the photoresist to remain insoluble in the developer.

An additional photoresist bake step (post exposure bake, or PEB) may occur after the exposure to radiation. For example, this may help in releasing acid leaving groups (ALGs) or other molecules that are significant in chemical amplification photoresist.

The photoresist layer is then developed using a developer. The developer may be an aqueous solution or an organic solution. The soluble portions of the photoresist layer are dissolved and washed away during the development step, leaving behind a photoresist pattern. One example of a common developer is aqueous tetramethylammonium hydroxide (TMAH). Other developers may include 2-heptanone, n-butyl acetate, isoamyl acetate, cyclohexanone, 5-methyl-2-hexanone, methyl-2-hydroxyisobutyrate, ethyl lactate or propylene glycol monomethyl ether acetate, n-pentyl acetate, n-butyl propionate, n-hexyl acetate, n-butyl butyrate, isobutyl butyrate, 2,5-dimethyl-4-hexanone, 2,6-dimethyl-4-heptanone, propyl isobutyrate, or isobutyl propionate. Generally, any suitable developer may be used. Sometimes, a post develop bake or “hard bake” may be performed to stabilize the photoresist pattern after development, for optimum performance in subsequent steps.

Generally, any etching step used herein may be performed using wet etching, dry etching, or plasma etching processes such as reactive ion etching (RIE) or inductively coupled plasma (ICP), or combinations thereof, as appropriate. The etching may be anisotropic. Depending on the material, etchants may include carbon tetrafluoride (CF₄), hexafluoroethane (C₂F₆), octafluoropropane (C₃F₈), fluoroform (CHF₃), difluoromethane (CH₂F₂), fluoromethane (CH₃F), trifluoromethane (CHF₃), carbon fluorides, nitrogen (N₂), hydrogen (H₂), oxygen (O₂), argon (Ar), xenon (Xe), xenon difluoride (XeF₂), helium (He), carbon monoxide (CO), carbon dioxide (CO₂), fluorine (F₂), chlorine (Cl₂), oxygen (O₂), hydrogen bromide (HBr), hydrofluoric acid (HF), nitrogen trifluoride (NF₃), sulfur hexafluoride (SF₆), boron trichloride (BCl₃), ammonia (NH₃), bromine (Br₂), or the like, or combinations thereof in various ratios. For example, silicon dioxide can be wet etched using hydrofluoric acid and ammonium fluoride. Alternatively, silicon dioxide can be dry etched using various mixtures of CHF₃, O₂, CF₄, and/or H₂.

The gate electrode, and any other electrically conductive components, can be formed by the deposition of any suitable electrically conductive material. Examples of such materials may include polycrystalline silicon (polysilicon); metals such as Al, Zr, W, Ru, Co, Ni, Pt, Au, Co, Rh, Pd, Bi, Ti, Ta, and the like; composites like TIN, WN, or TaN; or alloys thereof. The material may be deposited, for example, via evaporation or sputtering, plating, ALD, CVD, or other suitable methods. Chemical-mechanical planarization (CMP) may be used to remove excess deposited material. The gate electrode may have a thickness 215 of about 10 nm to about 100 nm.

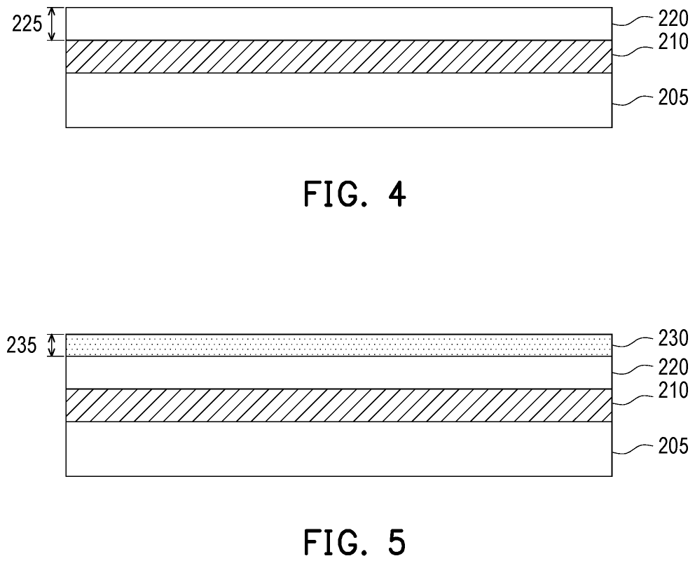

Next, in step 110 of FIG. 1 and as illustrated in FIG. 4, a gate dielectric layer 220 is formed upon the substrate, more specifically on the gate electrode 210. This may be formed in the same manner as described above. In particular embodiments, the gate dielectric layer 220 is formed from a high-k dielectric material. In some embodiments of the present disclosure, the high-k dielectric material has a dielectric constant higher than 5, or higher than 7, or higher than 10. Examples of high-k dielectric materials include those previously discussed. Other examples of suitable high-k dielectric materials can include Al₂O₃, HfO₂, HfLaO, HfSiO. Other suitable dielectric materials may include ferroelectric materials (whose dielectric constant may change with temperature) and oxide-nitride-oxide (ONO) films. The gate dielectric layer may have a thickness 225 of about 1 nm to about 10 nm.

Then, in step 115 of FIG. 1 and as illustrated in FIG. 5, a semiconductor layer 230 is formed upon the substrate, more specifically on the gate dielectric layer 220. The semiconductor layer can be formed using processes such as physical vapor deposition (PVD), chemical vapor deposition (CVD), or atomic layer deposition (ALD). The semiconductor layer may have a thickness 235 of about 1 nm to about 50 nm.

In particular embodiments, the semiconductor layer is formed from an oxide semiconductor. Examples of oxide semiconductors may include zinc oxide (ZnO), magnesium oxide (MgO), gadolinium oxide (GdO), gallium oxide (Ga₂O₃), tin oxide (SnOₓ), indium oxide (InOₓ), and binary, ternary, or quaternary combinations thereof. In more specific embodiments, the oxide semiconductor is InGaZnO (IGZO), which has the general formula InₓGa_{y}Zn_{z}O, where 0<x<1; 0≤y≤1; and 0≤z≤1. The InGaZnO is optionally doped with a metal, having the formula InₓGa_{y}Zn_{z}O:M, where M is Ti, Al, Ag, W, Ce, Sn, V, or Sc.

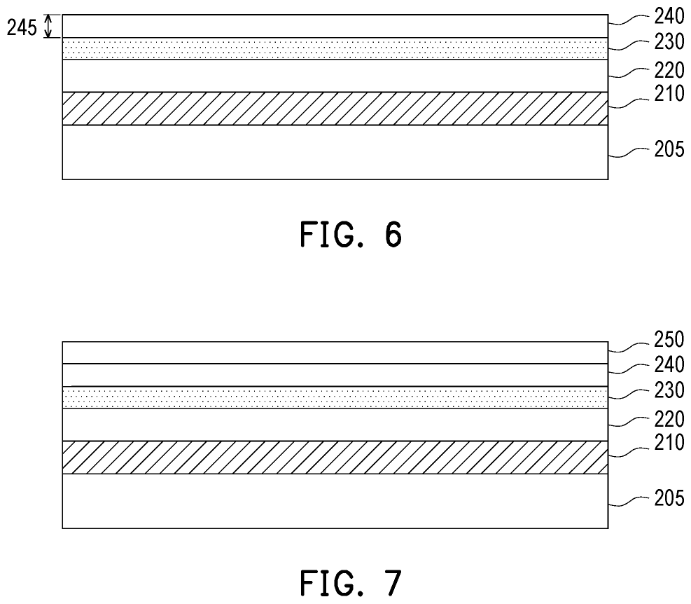

Continuing, in step 120 of FIG. 1 and as illustrated in FIG. 6, a colored light shielding layer 240 is formed upon the substrate, more specifically on the semiconductor layer 230. In particular embodiments as illustrated here, the colored light shielding layer 240 directly contacts the semiconductor layer 230. The colored light shielding layer reduces exposure of the semiconductor layer to radiation having a wavelength of about 10 nanometers (nm) to about 400 nm. The colored light shielding layer is not transparent, and desirably has very low light transmittance, especially for UV light.

In particular embodiments, the colored light shielding layer has a white, black, red, yellow, or gray color when viewed. White is typically considered the color that occurs when all visible light wavelengths are reflected and/or scattered. In contrast, the color black occurs when all visible light wavelengths are absorbed and not reflected/scattered. The color red occurs when light wavelengths of 620 nm to 750 nm are reflected. The color yellow occurs when light wavelengths of 570 nm to 590 nm are reflected. The color gray is intermediate between black and white. In more specific embodiments, the colored light shielding layer has a black color.

In accordance with some embodiments of the present disclosure, the colored light shielding layer can be formed from materials such as a metal oxide film, a p-type oxide semiconductor, or a perovskite. Examples of suitable metal oxides may include titanium dioxide (TiO₂, white); nickel oxide (NiO, black); iron oxide (Fe₂O₃, red); cobalt (II, III) oxide (Co₃O₄, black); manganese oxide (Mn₃O₄, black); cupric oxide (CuO, black); antimony trioxide (Sb₂O₃, white/gray); stannous oxide (SnO, black/red); and chromium oxide (Cr₂O₃, brown/green). Other metal oxides can include rare earth oxides, which are oxides of Sc, Y, La, Ce, Pr, Nd, Pm, Sm, Eu, Gd, Tb, Dy, Ho, Er, Tm, Yb, or Lu. Specific examples of rare earth oxides include cerium oxide (CeO₂, white/yellow); yttrium oxide (Y₂O₃, white); and neodymium oxide (Nd₂O₃, blue/gray). Rare earth oxides may provide the colored light shielding layer with high chemical/physical resistance. P-type oxide semiconductors may include CuO, NiO, Co₃O₄, and Cr₂O₃. The term perovskite as used herein refers to compounds having the same crystal structure as CaTiO₃. Perovskites may have the general formula ABO₃, where A is an alkaline earth or rare-earth element, and B is a 3d, 4d, or 5d transition element. Metal halide-derived perovskites also exist; for example those based on bismuth (Bi). In particular embodiments, the perovskite comprises Ca, Sr, or Bi. In other particular embodiments, high valence element oxides, such as those containing Ti⁴⁺, Ta⁵⁺, Cr⁴⁺, etc., are used as they restrain oxygen vacancy production. It is noted that the material of the colored light shielding layer is different from that of the semiconductor layer.

The materials that form the colored light shielding layer may be provided in the form of thin films, nanoparticles, or nanocomposites, as suitable. Nanoparticles have a diameter of between 1 and 100 nm. A nanocomposite is a solid made of more than one material (or phase), and has at least one dimension which is 100 nm or less.

The colored light shielding layer can be formed by PVD, CVD, ALD, or sputtering, or other suitable process. In some particular embodiments, during the formation of the colored light shielding layer or after the deposition thereof, the layer may also be treated with ozone. This may be performed by exposure to ozone or an ozone precursor. Oxygen atoms/radicals produced through ozone decomposition can compensate for any defects that may be present in the colored light shielding layer. The ozone treatment desirably fills any oxygen vacancies, and can improve the quality of dense oxide films.

Referring again to FIG. 6, the colored light shielding layer 240 has a thickness 245. In particular embodiments, the thickness 245 of the colored light shield layer is from about one angstrom (A) to about 100 angstroms. In more specific embodiments, the thickness 245 is from about 10 angstroms to about 100 angstroms.

Next, in step 125 of FIG. 1 and as illustrated in FIG. 7, a channel capping layer 250 is formed upon the substrate, more specifically upon the colored light shielding layer 240. The capping layer can reduce exposure of the semiconductor layer 230 to hydrogen atoms, which is known to damage oxide semiconductors. The channel capping layer can be formed by PVD, CVD, or ALD, or other suitable process. Suitable materials may include oxides such as silicon oxide; nitrides such as silicon nitride; or another dielectric material. It is noted that the presence of a channel capping layer is optional, and such layer does not need to be present to produce an operative transistor.

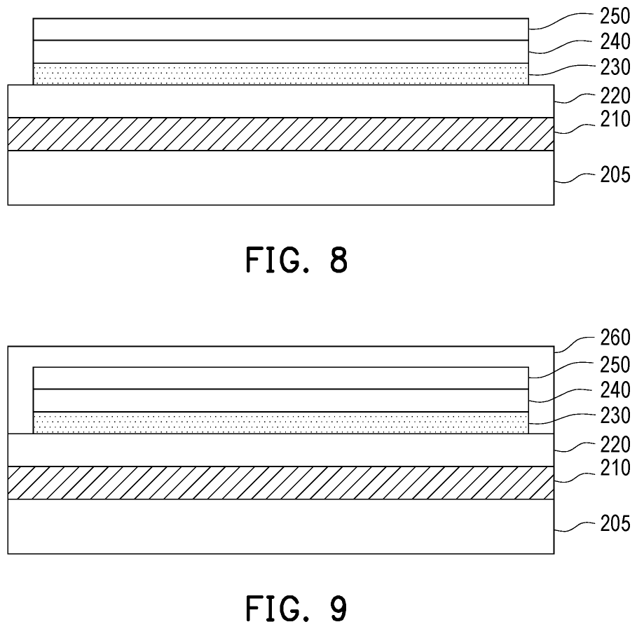

Then, in step 130 of FIG. 1 and as illustrated in FIG. 8, the semiconductor layer 230 is patterned. This may be done by applying and patterning a photoresist layer, etching to transfer the pattern to the semiconductor layer, and then removing the photoresist layer. As illustrated here, the colored light shielding layer 240 and the channel capping layer 250 are also patterned. It is noted that in this processing step, the colored light shielding layer 240 is already reducing the exposure of the semiconductor layer 230 to UV radiation.

Continuing, in step 135 of FIG. 1 and as illustrated in FIG. 9, an interlayer dielectric (ILD) layer 260 is applied over the semiconductor layer 230. Suitable methods and materials for forming a dielectric layer have been previously described, and are applicable to this processing step as well. As illustrated here, the semiconductor layer 230 is encapsulated by the ILD layer 260.

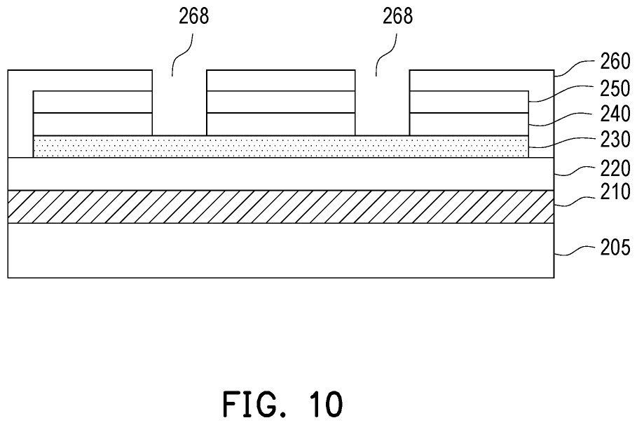

Then, in step 140 of FIG. 1 and as illustrated in FIG. 10, etching is performed to form source/drain (S/D) regions 268 that contact the semiconductor layer 230. A photoresist layer is applied to the ILD layer and patterned, and different etch recipes are used to etch through each layer. As illustrated here, the S/D regions are the empty volume that extend through the ILD layer 260, the channel capping layer 250, and the colored light shielding layer 240.

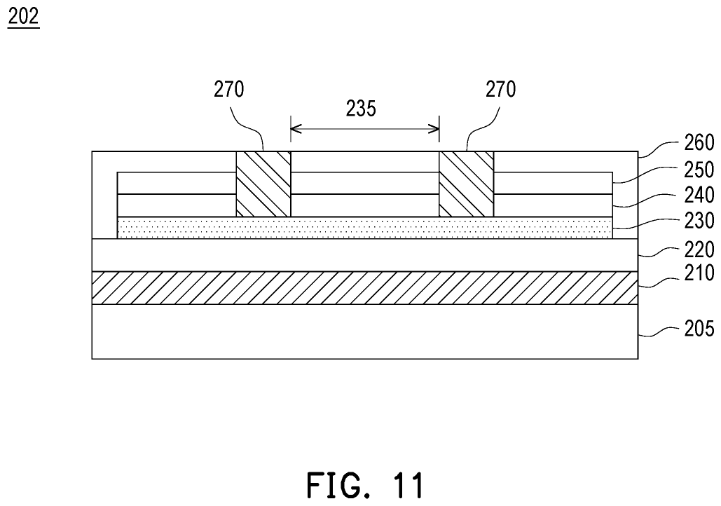

Next, in step 145 of FIG. 1 and as illustrated in FIG. 11, an electrically conductive material is deposited into the S/D regions to form S/D electrodes 270. The same methods and materials as described above for forming the gate electrode 210 are applicable to this processing step as well. This figure also illustrates one example of the final bottom-gate transistor 202. The semiconductor channel length 235 between the S/D electrodes 270 may be from about 1 nanometer to about 100 nanometers.

More generally, the gate dielectric layer 220 separates the gate electrode 210 from the source and drain electrodes 270. The semiconductor layer 230 bridges the S/D electrodes, and is in contact with the gate dielectric layer 220. The semiconductor layer 230 can also be considered as separating the gate electrode 210 from the S/D electrodes 270. Put another way, the S/D electrodes and the gate electrode are on opposite sides of the semiconductor layer/gate dielectric layer.

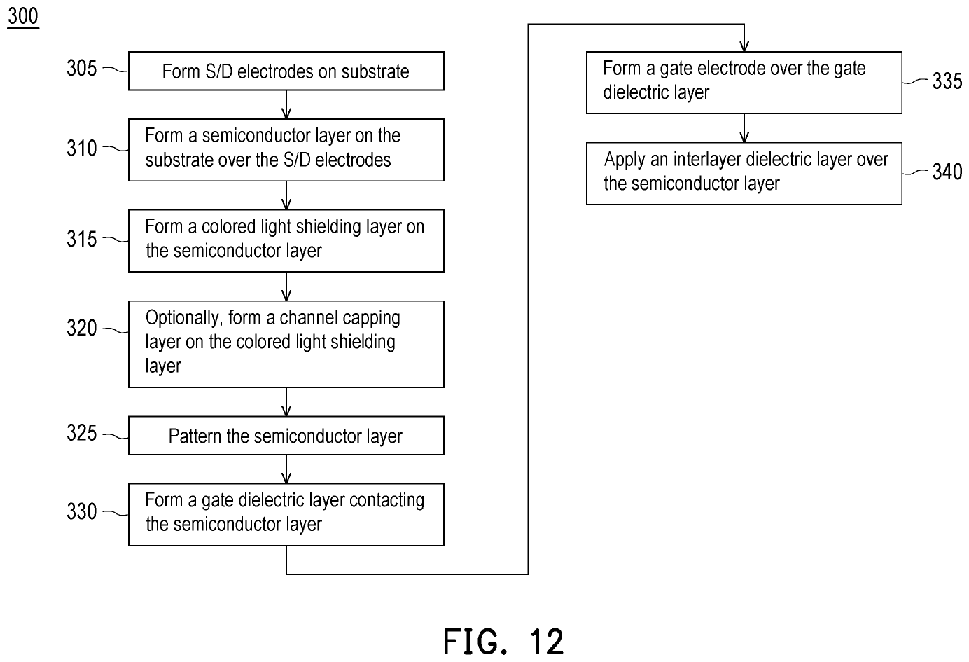

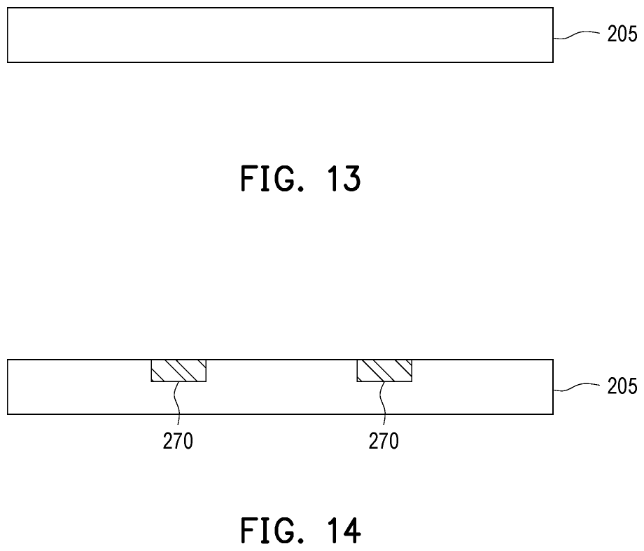

FIG. 12 is a flow chart illustrating a second method 300 for making a transistor, in accordance with some embodiments of the present disclosure. FIGS. 13-20 illustrate various steps of the second method, and these figures are discussed together. These figures are illustrated with reference to a top-gate transistor.

FIG. 13 again illustrates the beginning state of the substrate 205 prior to making the transistor. Next, in step 305 of FIG. 12 and as illustrated in FIG. 14, S/D electrodes 270 are formed on or in the substrate 205. As illustrated here, in contrast to the process described in FIGS. 2-11, the S/D electrodes 270 are shown in the substrate 205. This may be done, for example, by ion implantation. Briefly, an ion implanter is used to implant atoms into a silicon crystal lattice, modifying the conductivity of the lattice in the implanted location. An ion implanter generally includes an ion source, a beam line, and a process chamber. The ion source produces the desired ions (here, for example, Co, Ti, Ni, Pt, or Pb, depending on desired N- or P-type electrode). The beam line organizes the ions into a beam having high purity in terms of ion mass, energy, and species. The ion beam is then used to irradiate the wafer substrate in a process chamber. The ion beam strikes the exposed regions on the wafer substrate, and the ions can be implanted into the substrate as dopants at desired depths. Alternatively, the substrate can be partially etched, followed by blanket deposition of a metal, following by annealing in which the metal reacts with the underlying exposed silicon. Unreacted metal can then be removed, for example with a selective etch process.

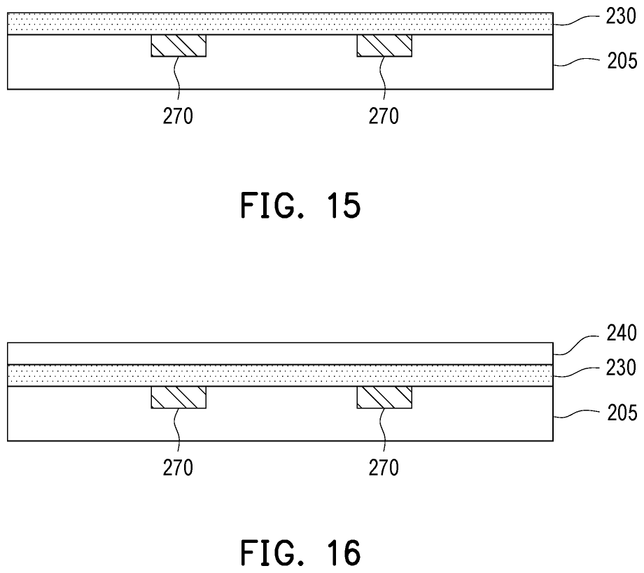

Next, in step 310 as illustrated in FIG. 15, the semiconductor layer is formed upon the substrate, specifically over the S/D electrodes 270. Then, in step 315 as illustrated in FIG. 16, the colored light shielding layer 240 is formed upon the semiconductor layer 230. Again, in particular embodiments, the colored light shielding layer 240 directly contacts the semiconductor layer 230. The layer may also be treated with ozone during the formation of the colored light shielding layer or after the deposition thereof. It is noted that the S/D electrodes should be entirely covered by the semiconductor layer and/or the colored light shielding layer, as exposure to oxygen may cause adhesion problems with the S/D electrodes due to oxidation, especially when the S/D electrodes are made of a metal.

If desired, in optional step 320 of FIG. 12, a channel capping layer 250 is formed over the semiconductor layer 230, which may also be on the colored light shielding layer 240.

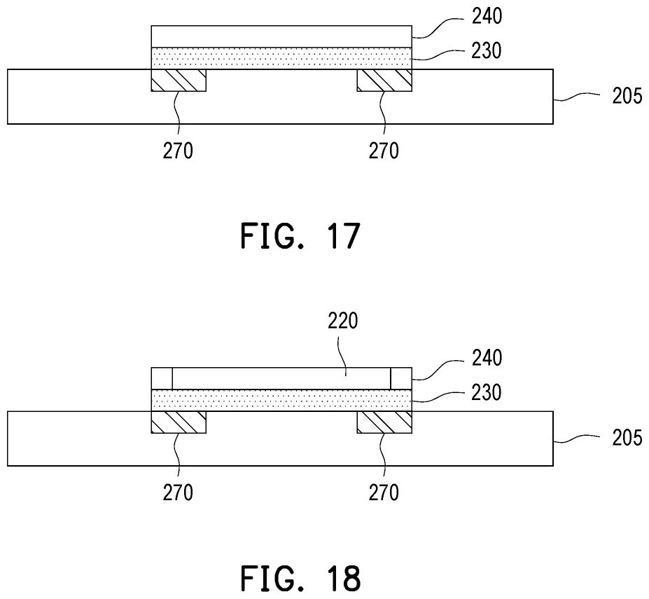

Next, in step 325 of FIG. 12 and as illustrated in FIG. 17, the semiconductor layer 230 is patterned. The semiconductor layer 230 is patterned so as to contact both S/D electrodes 270. Continuing, in step 330 of FIG. 12 and as illustrated in FIG. 18, a gate dielectric layer 220 is formed that contacts the semiconductor layer 230. As illustrated here, the colored light shielding layer 240 must be etched prior to forming the gate dielectric layer. However, the gate dielectric layer 220 is shorter than the semiconductor layer 230, and so portions of the colored light shielding layer 240 are still present.

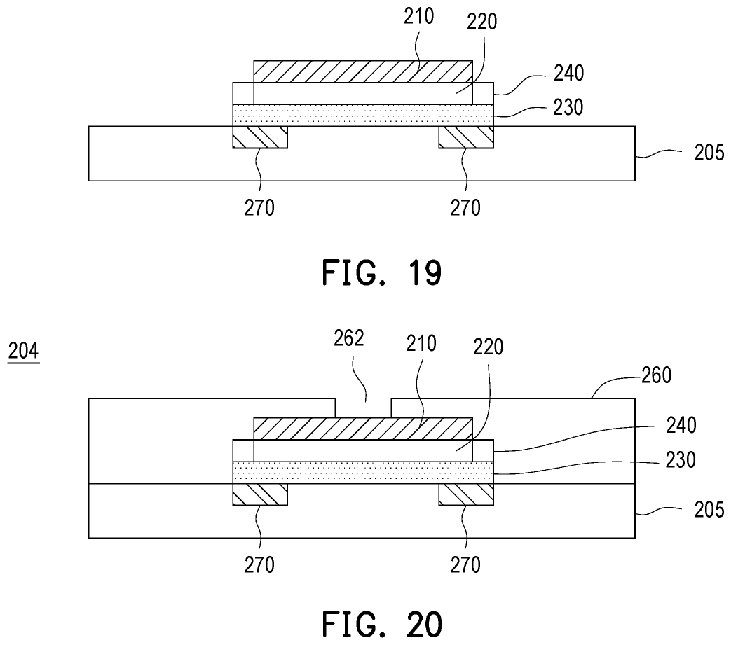

Then, in step 335 of FIG. 12 and as illustrated in FIG. 19, a gate electrode 210 is formed over the gate dielectric layer 220. Finally, in step 340 of FIG. 12 and as illustrated in FIG. 20, an interlayer dielectric layer 260 is formed over the semiconductor layer 230. As illustrated here, the ILD layer 260 is also etched to form a gap 262 that allows electrical contact with the gate electrode 210. This figure also illustrates the final top-gate transistor 204. It is noted the semiconductor layer 230 does not need to fully cover the source/drain electrodes 270.

In some embodiments of the second method 300 for making a transistor, when a top-gate transistor is made, the colored light shielding layer may be made from a material that also acts as a dielectric. Such dielectric materials may include a metal oxide film, a p-type oxide semiconductor, or a perovskite, as previously described. In these embodiments, the colored light shielding layer 240 may also be used as the gate dielectric layer, and a separate gate dielectric layer does not need to be formed.

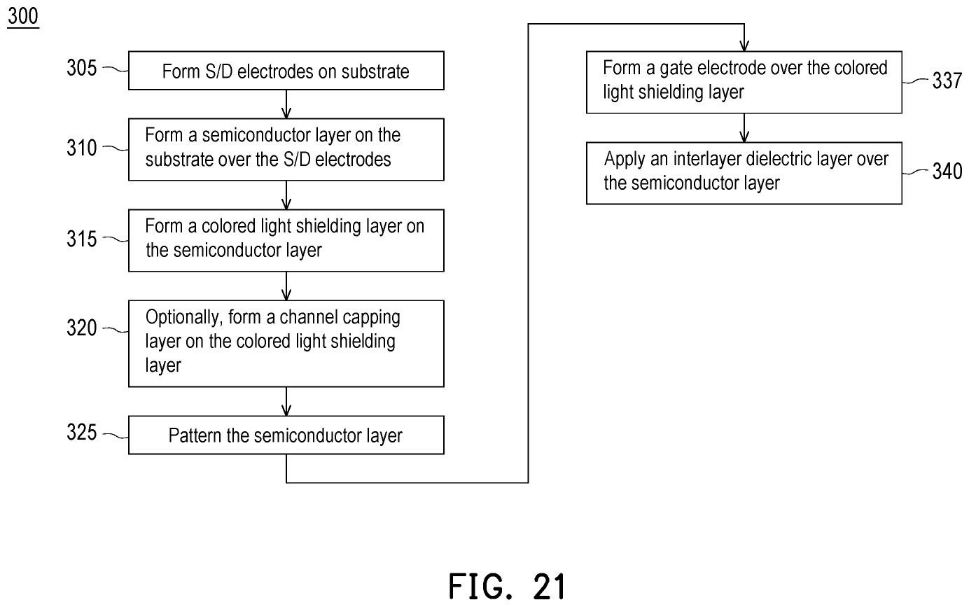

FIG. 21 is a flow chart illustrating such embodiments of the second method 300 for making a transistor, in accordance with some embodiments of the present disclosure. Initially, steps 305, 310, 315, 320 (optional), and 325 are identical to the steps of FIG. 12 and as illustrated in FIGS. 13-17. It is noted that in these embodiments, the material used in the semiconductor layer 230 differs from the material used in the colored light shielding layer 240.

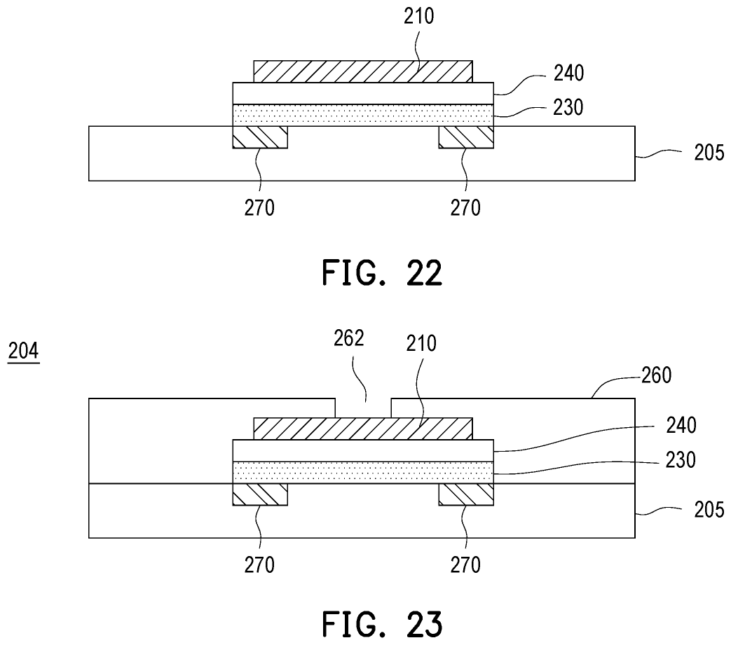

Then, in step 337 of FIG. 21 and as illustrated in FIG. 22, a gate electrode 210 is formed over the colored light shielding layer 240. Then, in step 340 of FIG. 21 and as illustrated in FIG. 23, an interlayer dielectric layer 260 is formed over the semiconductor layer 230. Again, the ILD layer 260 includes a gap 262 that allows electrical contact with the gate electrode 210.

It is noted that in some applications, the gate electrode 210 is referred to as the write line, one S/D electrode 270 is referred to as the source line, and the other S/D electrode 270 is referred to as the bit line. These terms can be interchanged, and should be considered as also being used in the discussion of transistors herein. It is also noted that while FIGS. 1-23 describe forming a single transistor on a wafer substrate, during chip production large numbers of transistors are formed concurrently on the wafer substrate. The present disclosure should be construed accordingly.

The resulting transistor can be used in several different applications and systems. The transistor can be used in charge coupled devices (CCDs), complementary metal-oxide semiconductor (CMOS) image sensors, contact image sensors (CIS), and ambient light sensors (ALS). Such sensors can be used in systems such as mobile telephones, facial recognition systems, or as motion sensors for automotive applications, security applications, energy efficiency, etc. Random access memory uses a transistor to read and write bit values to a memory cell (nonvolatile or volatile). The transistor may be integrated with a Micro-Electro-Mechanical Systems (MEMS) device on a single chip. The MEMS device may include a plurality of elements formed from metal, polysilicon, dielectric, and/or other materials. The MEMS device may include mechanical structures, electrical structures, or fluid structures.

The addition of the colored light shielding layer provides multiple advantages. First, the presence of the colored light shielding layer reduces the number of defects in the semiconductor layer which can be generated by exposure to UV light, particularly when an oxide semiconductor is used. For example, UV light is used in processes such as curing some photoresists or forming an intermetal dielectric (IMD) layer in a back-end-of-line (BEOL) process. UV curing is also widely used in applications such as adhesive bonding and assembly, component marking, gasketing and sealing, potting, masking, encapsulating and conformal coating, wafer masking, wafer contamination inspection, and wafer polishing inspection. Second, the surface of an oxide semiconductor is usually hydrophilic, and the presence of the colored light shielding layer reduces hydrogen and water absorption which can otherwise occur in the semiconductor layer due to exposure during various manufacturing steps. Third, a stable layer with high chemical and physical resistance can reduce chemical and physical damage to the semiconductor layer that might otherwise occur during various manufacturing steps through which the wafer substrate passes during chip production. Finally, the use of the colored light shielding layer also reduces the number of oxygen vacancy states and photogenerated holes that may arise in the semiconductor layer. This in turn reduces any changes in charge carrier concentration which might otherwise occur across the semiconductor layer. Charge carrier concentration is a key factor in maintaining high carrier mobility and high driving speed, which improves the reliability of the overall semiconductor device.

The colored light shielding layer is illustrated here using two-dimensional field effect transistors (FET). However, the colored light shielding layer may also be applied for use in three-dimensional transistors such as FinFETs and Gate-All-Around transistors.

Disclosed herein in various embodiments are transistors, comprising a colored light shielding layer over a semiconductor layer. The colored light shielding layer reduces exposure of the semiconductor layer to radiation having a wavelength of about 10 nanometers (nm) to about 400 nm. The colored light shielding layer has a white, black, red, yellow, or gray color.

Also disclosed in various embodiments are transistors, comprising: a write line; a semiconductor layer; a source line and a bit line; and a colored light shielding layer. The source line and the bit line contact the semiconductor layer. The colored light shielding layer comprises a dielectric material, and can act as a gate dielectric layer. Examples of such materials include TiO₂, NiO, Fe₂O₃, Co₃O₄, Mn₃O₄, CuO, Sb₂O₃, SnO, Cr₂O₃, a rare earth oxide, CeO₂, Y₂O₃, Nd₂O₃, or a perovskite comprising Ca, Sr, or Bi. In some embodiments, the colored light shielding layer contacts the semiconductor layer and the write line, for example being located between them. In some alternative embodiments, a separate gate dielectric layer contacts the write line and the semiconductor layer. In additional embodiments, a channel capping layer may be located over the colored light shielding layer.

Also disclosed in various embodiments are transistors, comprising: a write line; a gate dielectric layer; an oxide semiconductor layer; a source line and a bit line; a colored light shielding layer; and a channel capping layer. The gate dielectric layer contacts the write line. The oxide semiconductor layer contacts the gate dielectric layer. The source line and the bit line contact the oxide semiconductor layer. The colored light shielding layer contacts the oxide semiconductor layer. The colored light shielding layer comprises TiO₂, NiO, Fe₂O₃, Co₃O₄, Mn₃O₄, CuO, Sb₂O₃, SnO, Cr₂O₃, a rare earth oxide, CeO₂, Y₂O₃, Nd₂O₃, or a perovskite comprising Ca, Sr, or Bi. The channel capping layer is located over the colored light shielding layer.

Also disclosed in various embodiments are transistors, comprising: a write line; a semiconductor layer; a source line and a bit line; a colored light shielding layer; and a channel capping layer. The gate dielectric layer contacts the write line. The oxide semiconductor layer contacts the gate dielectric layer. The source line and the bit line contact the oxide semiconductor layer. The colored light shielding layer contacts the oxide semiconductor layer. The colored light shielding layer comprises TiO₂, NiO, Fe₂O₃, Co₃O₄, Mn₃₀₄, CuO, Sb₂O₃, SnO, Cr₂O₃, a rare earth oxide, CeO₂, Y₂O₃, Nd₂O₃, or a perovskite comprising Ca, Sr, or Bi. The channel capping layer is located over the colored light shielding layer.

Also disclosed herein are various methods for making a transistor, comprising: forming a semiconductor layer on a substrate; and forming a colored light shielding layer over the semiconductor layer. The colored light shielding layer reduces exposure of the semiconductor layer to radiation having a wavelength of about 10 nanometers (nm) to about 400 nm.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A transistor, comprising a colored light shielding layer over a semiconductor layer, wherein the colored light shielding layer reduces exposure of the semiconductor layer to radiation having a wavelength of about 10 nanometers (nm) to about 400 nm;
and wherein the colored light shielding layer has a white, black, red, yellow, or gray color.

2. The transistor of claim 1, wherein the colored light shielding layer is formed from a metal oxide film, a p-type oxide semiconductor, or a perovskite.

3. The transistor of claim 1, wherein the colored light shielding layer comprises TiO₂, NiO, Fe₂O₃, Co₃O₄, Mn₃₀₄, CuO, Sb₂O₃, SnO, Cr₂O₃, a rare earth oxide, CeO₂, Y₂O₃, Nd₂O₃, or a perovskite comprising Ca, Sr, or Bi.

4. The transistor of claim 1, wherein the colored light shielding layer is treated with ozone.

5. The transistor of claim 1, wherein the colored light shielding layer has a thickness of about one angstrom (A) to about 100 angstroms.

6. The transistor of claim 1, wherein the semiconductor layer has a channel length of about one nm to about 100 nm.

7. The transistor of claim 1, wherein the semiconductor layer is formed from an oxide semiconductor.

8. The transistor of claim 7, wherein the oxide semiconductor is InGaZnO which is optionally doped with a metal.

9. The transistor of claim 8, wherein the oxide semiconductor is doped with the metal, and the metal is Ti, Al, Ag, W, Ce, Sn, V, or Sc.

10. The transistor of claim 1, further comprising a channel capping layer over the semiconductor layer.

11. The transistor of claim 10, wherein the channel capping layer comprises a silicon oxide, a silicon nitride, or another dielectric material.

12. The transistor of claim 1, further comprising a dielectric layer.

13. The transistor of claim 12, wherein the dielectric layer comprises a high-k dielectric material, an oxide-nitride-oxide (ONO) material, or a ferroelectric material.

14. A transistor, comprising:
a write line;
a semiconductor layer;
a source line and a bit line contacting the semiconductor layer; and
a colored light shielding layer contacting the semiconductor layer and located between the semiconductor layer and the write line, wherein the colored light shielding layer comprises TiO₂, NiO, Fe₂O₃, Co₃O₄, Mn₃O₄, CuO, Sb₂O₃, SnO, Cr₂O₃, a rare earth oxide, CeO₂, Y₂O₃, Nd₂O₃, or a perovskite comprising Ca, Sr, or Bi.

15. The transistor of claim 14, further comprising a channel capping layer over the colored light shielding layer.

16. The transistor of claim 14, further comprising a gate dielectric layer contacting the write line.

17. A method for making a transistor, comprising:
forming a semiconductor layer on a substrate;
forming a colored light shielding layer over the semiconductor layer, wherein the colored light shielding layer reduces exposure of the semiconductor layer to radiation having a wavelength of about 10 nanometers (nm) to about 400 nm.

18. The method of claim 17, further comprising treating the colored light shielding layer with ozone.

19. The method of claim 17, further comprising forming a channel capping layer upon the colored light shielding layer.

20. The method of claim 17, wherein the colored light shielding layer directly contacts the semiconductor layer.
